(19) United States
(12) Patent Application Publication
(10) Pub. No.: US 2020/0017962 A1
(43) Pub. Date: Jan. 16, 2020

(54) Methods for Increasing Hydrogen Trapping Vacancies in Materials

(71) Applicant: IH IP Holdings Limited, St. Helier (JE)

(72) Inventors: Darren R. Burgess, Charlotte, NC (US); Michael Raymond Greenwald, Indian Trail, NC (US); Brent W. Barbee, Stanfield, NC (US)

(21) Appl. No.: 16/497,479

(22) PCT Filed: Mar. 28, 2018
(86) PCT No.: PCT/US2018/024786

§ 371 Date: Sep. 25, 2019

Related U.S. Application Data
(60) Provisional application No. 62/478,088, filed on Mar. 29, 2017.

(51) Int. Cl. C23C 16/18; C01B 13/14; C23C 16/52; C03C 17/09; C01B 3/00

(52) U.S. Cl. CPC C23C 16/18; C01B 13/14; C01B 3/0031; C03C 17/09; C23C 16/52

(57) ABSTRACT

Methods and apparatus for increasing vacancies in a metallic structure are disclosed and for improving a hydrogen loading ratio in the metallic structure. The metallic structure comprises one or more transition metals or metal alloys. The metallic structure is prepared by forming a metal organic precursor and reducing the precursor to a metallic structure, in which a coordination number of the metal atoms is reduced and the vacancies in the metallic structure are increased.

### PRIORITY CLAIM

This application is a U.S. National Stage application of International Application No. PCT/US18/024786, filed on Mar. 28, 2018, which claims priority to U.S. Provisional Patent Application No. 62/478,088 filed on Mar. 29, 2017, and the entire contents of which are hereby incorporated by reference herein.

### TECHNICAL FIELD

The present invention relates generally to increasing defects or vacancies in a transition metal structure, and more specifically, to reducing the coordination numbers of metal atoms in a metallic structure to increase hydrogen trapping vacancies.

### BACKGROUND

Several transition metals are known to have a good hydrogen-absorption capacity and can be used for hydrogen storage. It is also well known that a few transition metals, when loaded with hydrogen/deuterium, can be used as a catalyst in exothermic reactions. Studies show that the amount of abnormal heat generated in such an exothermic reaction depends on the hydrogen loading ratio of the catalyst used in the reaction.

A hydrogen loading ratio measures, in a transition metal lattice loaded with hydrogen/deuterium, a ratio of the number of hydrogen/deuterium atoms to the number of metal atoms in the lattice. A hydrogen loading ratio reflects the amount of hydrogen/deuterium that has been loaded into the metal lattice. Under normal conditions, a transition metal lattice can achieve a hydrogen loading ratio of 0.8-0.9. It is generally difficult to achieve a hydrogen loading ratio close to or higher than 1.0. Various techniques can be utilized to increase the hydrogen loading ratio in a transition metal. However, those techniques usually require high pressure and high temperature exposure. In some cases, an excessive time requirement on the order of days may be needed. And in some cases, there is a lack of predictability and control.

Hence a need exists in the art for improving the hydrogen loading capacity of a transition metal lattice.

The Background section of this document is provided to place embodiments of the present invention in technological and operational context, to assist those of skill in the art in understanding their scope and utility. Approaches descried in the Background section could be pursued, but are not necessarily approaches that have been previously conceived or pursued. Unless explicitly identified as such, no statement herein is admitted to be prior art merely by its inclusion in the Background section.

### SUMMARY

The following presents a simplified summary of the disclosure in order to provide a basic understanding to those of skill in the art. This summary is not an extensive overview of the disclosure and is not intended to identify key/critical elements of embodiments of the invention or to delineate the scope of the invention. The sole purpose of this summary is to present some concepts disclosed herein in a simplified form as a prelude to the more detailed description that is presented later.

The present application discloses exemplary methods and apparatus for increasing vacancies in a metallic structure. More vacancies in a metallic structure improve the hydrogen loading capacity of the metallic structure.

In some embodiments, the vacancies in a transition metal structure are increased by reducing the coordination number of metal atoms located at the intersections of crystal facets. The transition metal or metal alloy comprises one or more of the following metals: titanium (Ti), zirconium (Zr), hafnium (Hf), chromium (Cr), vanadium (V), niobium (Nb), tantalum (Ta), molybdenum (Mo), tungsten (W), iron (Fe), ruthenium (Ru), rhodium (Rh), iridium (Ir), nickel (Ni), palladium (Pd), platinum (Pt), copper (Cu), silver (Ag), gold (Au), zinc (Zn), aluminum (Al), indium (In), tin (Sn), and lead (Pb).

In one embodiment, a metal organic liquid phase precursor comprising the transition metal or metal alloy is prepared. For example, the metal organic liquid precursor may comprise a metal acetylacetonate, a formaldehyde solution and a 1-octylamine solution. The metal organic liquid phase precursor is then reduced to a metallic structure. For example, the process of reducing the metal organic liquid precursor may comprise the following steps. First, the metal acetylacetonate solution is heated at a first temperature for a first time period. The heated solution is then cooled to room temperature and the solution is centrifugally separated to achieve a solid product of nanocrystals. The solid product of nanocrystals is rinsed with ethanol or acetone or a mixture of both. In some embodiments, the solid product of nanocrystals is rinsed with ethanol or acetone or a mixture of both for multiple times, e.g., two to five times.

In one embodiment, the process of reducing the metal acetylacetonate solution to a metallic structure comprises heating a substrate made of a borosilicate glass to a first temperature and depositing the metal acetylacetonate onto the substrate using a pulse sequence. In one embodiment, the pulse sequence comprises the metal acetylacetonate carried by N₂, N₂ purge, air, and N₂ purge.

In some embodiments, the coordination number of metal atoms in a metallic oxide film is reduced. The metallic oxide film comprises a transition metal or metal alloy. The metallic oxide film may be prepared in accordance to the following process. First, a metal organic solid phase precursor is dissolved to form a solution. The solution is then injected into an argon carrier gas in a vaporizing cell at a first temperature to produce a vaporized precursor. The vaporized precursor is then deposited onto a heated substrate. The substrate is heated to or above a pre-determined temperature required for removal of the organic portion of the precursor. Once the organic portion is removed from the precursor, a thin film of metal oxide is formed on the substrate. This is because oxidation takes place only on or near the substrate. The metal atoms in the metallic oxide film have a reduced coordination number at the film surface. In one embodiment, the metal organic solid phase precursor comprises a metal 2,2,6,6-tetramethylheptane-3,5-dionato dissolved into n-butylhexane. In one embodiment, the process further comprises heating the metallic oxide film in an inert gas atmosphere, reducing the metallic oxide to remove oxygen atoms, and creating vacancies to reduce the coordination number of the metal atoms in the metallic oxide film.

In some embodiments, the coordination number of metal atoms in a metal oxide film is reduced by subliming a metal organic precursor to produce a sublimed precursor at a first temperature. The precursor comprises a first transition metal. The sublimed precursor is deposited onto a substrate to form a metallic film. Oxygen is introduced to produce a metal oxide in the metallic film. The metallic film is then doped with a second transition metal. The second transition metal creates a vacancy in the metallic film, which reduces the coordination number of the first transition metal. Examples of the first or second transition metal include one or more of the following: Ti, Zr, Hf, Cr, V, Nb, Ta, Mo, W, Fe, Ru, Rh, Ir, Ni, Pd, Pt, Cu, Ag, Au, Zn, Al, In, Sn, and Pb. In one embodiment, the metal precursor comprises a metal 2,2,6,6-tetramethylheptane-3,5-dionato dissolved in a butylhexane.

### BRIEF DESCRIPTION OF FIGURES

FIG. 1 illustrates an exemplary chromium crystal body-centered cubic structure.

FIG. 2 illustrates an exemplary rutile-phase titanium oxide crystal structure.

FIG. 3 illustrates an exemplary palladium lattice structure comprising a (100) plane and a (111) plane.

FIG. 4 is a flow chart illustrating an exemplary process of reducing a coordination number of metal atoms in a metallic structure using a metal organic liquid phase precursor.

FIG. 5 is a flow chart illustrating an exemplary process of reducing a coordination number of metal atoms in a metallic structure using a metal organic solid phase precursor.

FIG. 6 is a flow chart illustrating an exemplary process of reducing a coordination number of metal atoms in a metallic structure by subliming a metal organic precursor.

### DETAILED DESCRIPTION

For simplicity and illustrative purposes, the present invention is described by referring mainly to an exemplary embodiment thereof. In the following description, numerous specific details are set forth in order to provide a thorough understanding of the present invention. However, it will be readily apparent to one of ordinary skill in the art that the present invention may be practiced without limitation to these specific details. In this description, well known methods and structures have not been described in detail so as not to unnecessarily obscure the present invention.

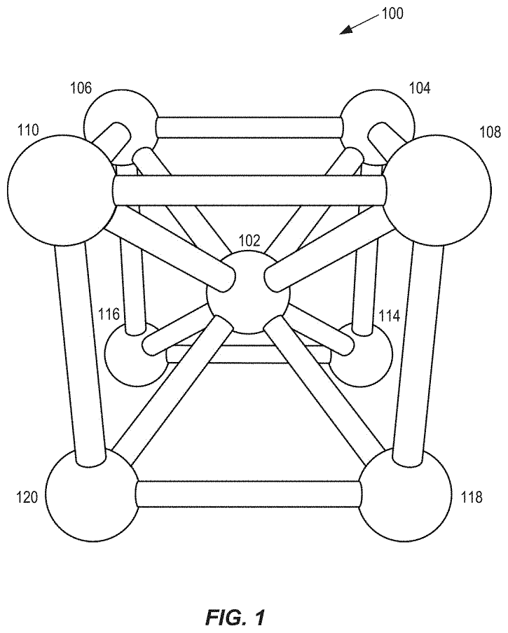

FIG. 1 illustrates a body-centered cubic crystal structure 100. Chromium is one exemplary transition metal having a bcc crystal structure. In a perfect bcc crystal structure 100, each atom on a corner of the lattice, for example, atom 104, 106, 108, 110, etc., is adjacent to ten atoms, i.e., having a coordination number of 10. Each atom located in the center of the lattice, e.g., atom 102, is adjacent to eight atoms, having a coordination number of 8. In the example of chromium, chromium atom 102 has eight nearest neighboring atoms: 104, 106, 108, 110, 114, 116, 118, and 120. Chromium atom 110 has ten nearest neighboring atoms: 102, 106, 108, 120, and six other neighboring atoms that are not shown. When a chromium atom is removed from the bcc crystal structure, a vacancy is created and the coordination number of any atom adjacent to the removed atom is reduced. For example, when chromium atom 102 is removed from the bcc crystal structure, each atom 104-120 becomes nine-coordinated, reduced from ten-coordinated. Thus, in a metallic lattice structure, creating vacancies leads to reduced coordination number of the metal atoms in the lattice structure.

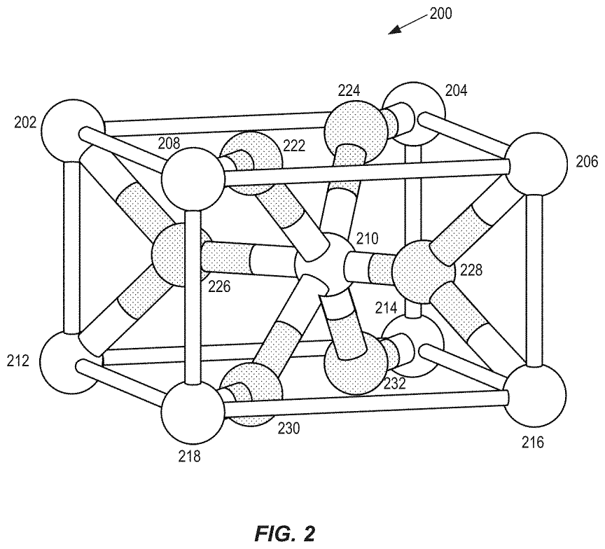

FIG. 2 illustrates a rutile phase metal oxide lattice structure 200. Titanium oxide is an exemplary metal oxide having a rutile phase lattice structure. In the lattice structure 200, the light colored atoms 202, 204, 206, 208, 210, 212, 214, 216, and 218 are metal atoms. The dark colored atoms, 222, 224, 226, 228, 230, and 232 are oxygen atoms. Each metal atom has six oxygen atoms as its nearest neighbors. If one or more oxygen atoms are removed from the lattice structure, each of its nearest metal atoms becomes five-coordinated. The coordination number of the metal atoms adjacent to the removed oxygen atom is reduced from six to five.

Density functional theory calculation suggests that an inverse correlation exists between the ability of a host atom to bind a hydrogen atom and the host atom's coordination number. The present disclosure teaches methods and processes that create vacancies in a metallic lattice structure resulting in reduced coordination numbers of metal atoms in a crystal lattice structure. In a lattice structure in which the coordination number of the host atoms is reduced, more hydrogen atoms can be absorbed by the lattice structure, increasing the hydrogen loading ratio of the lattice structure.

In some embodiments, the coordination number of metal atoms in a metallic structure of a transition metal or metal alloy is reduced by dissolving the transition metal or metal alloy into a metal acetylacetonate to form a metal organic liquid phase precursor. The metal organic liquid phase precursor is reduced to a crystalline metallic structure. On the surface of the metallic structure, the coordination number of the transition metal at an intersection of two crystal facets is reduced.

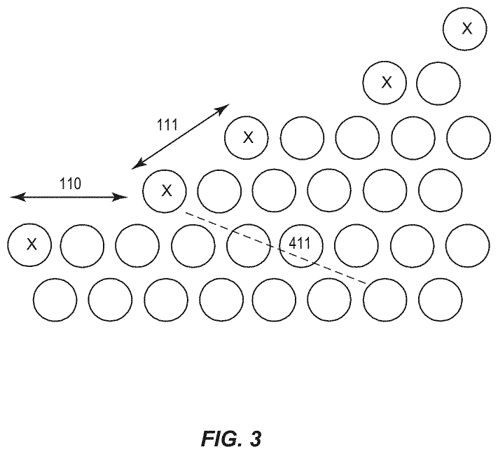

FIG. 3 illustrates an exemplary face-centered cubic structure in which the coordination number of atoms on certain crystal planes are reduced. Palladium is an exemplary metal that has a face-centered cubic structure. In FIG. 3, the nanocrystal structure has a large area {411} facet. The {411} plane is faceted into {100} and {111} planes. In the case of palladium, each palladium atom on the {411} plane is 12-coordinated. The palladium atoms on the {100} planes are 8-coordinated and those on the {111} planes are 9-coordinated. The palladium atoms at the intersection of the {100} and the {111} planes are only 5-coordinated. The reduction in coordination numbers of the atoms on the {100} and {111} planes increases the ability of the palladium nanocrystal structure to trap H atoms.

To prepare the above-described palladium nanocrystal structures, in some embodiments, the metal organic liquid phase precursor is prepared by mixing 4 to 5 mg of palladium acetylacetonate with 0.04 to 0.05 mL of 40% formaldehyde solution and 8 to 10 mL of 1-octylamine. The liquid phase precursor is placed in a Teflon lined metal pressure chamber, e.g., an autoclave, and is heated at a temperature between 200° C. and 300° C. for a minimum of five fours. After heating, the liquid phase precursor is cooled to room temperature. The solid product in the liquid phase precursor is centrifugally separated and then rinsed with ethanol, acetone, or a mixture of the two. In some embodiments, the solid product is rinsed two to five times. The final solid product comprises palladium nanocrystals in which the surface atoms have a reduced coordination number.

In another embodiment, the metal organic liquid phase precursor is an iridium acetylacetonate. The precursor is deposited onto a substrate made of borosilicate glass by atomic layer deposition using a pulse sequence. For example, the substrate temperature is maintained between 350 and 400° C. and the total pressure is between 7.5 and 15 Torr. The pulse sequence comprises iridium acetylacetonate carried by nitrogen (N₂), N₂ purge, air, N₂ purge. The iridium precursor and air pulses are kept equivalent in the range of 0.5 to 2.5 s. N₂ purge pulses are maintained at approximately 0.5 s. The flow rate of N₂ is in the range of 350 to 450 standard cubic centimeter per minute (sccm). The flow rate of air is in the range of 5 to 40 sccm. In the iridium film formed on the substrate, the iridium atoms on the surface of the film have a reduced coordination number, e.g., smaller than 9. Because of the iridium atoms with a reduced coordination number, the film has an enhanced ability to trap H atoms in the near surface layers.

A person skilled in the art can readily modify the ranges of temperature and pressure described in the above embodiments and find a range of conditions in which crystalline thin films and/or particles of various transition metals with reduced coordination can be created. Exemplary transition metals include but are not limited to: Ti, Zr, Hf, Cr, V, Nb, Ta, Mo, W, Fe, Ru, Rh, Ir, Ni, Pd, Pt, Cu, Ag, Au, Zn, Al, In, Sn, and Pb.

In some embodiments, vacancies in a metal oxide film can be enhanced by reducing the oxygen in the metal oxide film. Removing oxygen from the metal oxide film reduces the coordination number of the metal atoms on the surface of the metal oxide film. In one embodiment, a ruthenium (Ru) oxide film is first formed by depositing a metal precursor onto a substrate. Oxygen is then removed from the near surface layers. In the partially reduced ruthenium oxide film, Ru atoms have a reduced coordination number due to the many vacancies created at the vacated oxygen lattice sites. For example, a ruthenium oxide film having a majority (110)-oriented crystal grains is deposited using a metal organic solid phase precursor, which is formed by dissolving ruthenium 2,2,6,6-tetramethylheptane-3,5-dionato in n-butylhexane. The precursor is then directly injected into a vaporizing cell via a carrier, e.g., argon gas. The temperature of the cell is maintained between 240 and 260° C. The flow rate of the solution is kept between 0.04 ml/min and 0.08 ml/min and the flow rate of the carrier gas is kept between 100 and 150 sccm. In one embodiment, the substrate is made of sapphire and is heated to 275 to 325° C. The film deposited onto the substrate comprises RuO₂ crystals. RuO₂ crystal structures are rutile (tetragonal) and the Ru atoms in a RuO₂ crystal structure have six nearest neighboring oxygen atoms, i.e., a coordination number of 6. The near surface Ru atoms in the {110} planes are a mixture of 5-coordinated and 6-coordinated. The 5-coordinated Ru atoms in the near surface layers have an increased capability of trapping hydrogen atoms. Furthermore, oxygen atoms in the near surface layers can be removed to reduce the coordination number of the Ru atoms. The O-vacancy sites lead to an increased ability of the film to trap hydrogen atoms.

A person skilled in the art can apply the above described methods and processes of metal oxide film deposition in a range of conditions whereby crystalline thin films of the following metals can be created with reduced coordination metal atoms on their respective surfaces: Ti, Zr, Hf, Cr, V, Nb, Ta, Mo, W, Fe, Ru, Rh, Ir, Ni, Pd, Pt, Cu, Ag, Au, Zn, Al, In, Sn, and Pb. The coordination number of the metal atoms can be further reduced by removing oxygen atoms to create O vacancies, resulting in an increased ability to trap hydrogen/deuterium atoms in the near surface layers.

In some embodiments, a method of reducing the coordination number of metal atoms in a metal oxide film comprises the following steps. First, a metal organic precursor is sublimed to produce a sublimed precursor at a first temperature. The sublimed precursor comprises a first transition metal. Second, the sublimed precursor is deposited onto a substrate to form a metallic film. Oxygen is then introduced to produce a metal oxide in the metallic film. The metallic film is also doped with a second transition metal, which creates vacancies in the metallic film and reduces the coordination number of the first transition metal. In some embodiments, the metal precursor comprises a metal 2,2,6,6-tetramethylheptane-3,5-dionato dissolved in a butylhexane. In some embodiments, the coordination number of the first transition metal atoms can be further reduced by removing the oxygen atoms in the metallic film. For instance, the oxygen atoms in the metallic film can be reduced by heating the metallic oxide film in an inert gas atmosphere. In some embodiments, the first transition metal comprises one of the following metal or an alloy of two or more of the following metals: Ti, Zr, Hf, Cr, V, Nb, Ta, Mo, W, Fe, Ru, Rh, Ir, Ni, Pd, Pt, Cu, Ag, Au, Zn, Al, In, Sn, and Pb.

In one embodiment, a rutile-phase titanium oxide (TiO₂) film having a majority (110)-oriented crystal grains is deposited on (110)-oriented sapphire using Ti 2,2,6,6-tetramethylheptane-3,5-dionato which is sublimed at 350 to 375° C. by a focused xenon-filament lamp. The sublimed precursor is carried by helium. Oxygen is added to the reactor. The total pressure is 2 to 5 Torr with equal partial pressures of O₂ and precursor plus carrier gas. The precursor partial pressure is 0.5 to 20 mTorr. The substrate temperature is 400 to 700° C. The film is doped with gallium (Ga) by mixing Ga (III) 2,2,6,6-tetramethylheptane-3,5-dionato physically into the Ti precursor at 0.1 to 7% by weight. When thoroughly mixed, the weight percentage of the Ga precursor corresponds to the atomic doping percentage in the film within +/−10%. When a Ga atom substitutes for a titanium (Ti) atom on the rutile lattice, the Ga dopant atom is compensated for by O vacancies or Ti interstitials, respectively. The following two defect equations capture the doping process:

Ga₂O₃↔2Ga′_{Ti}+3Oₒ^{x}+Vₒ^{..} (1)

TiO₂+2Ga₂O₃↔4Ga′_{Ti}+8Oₒ^{x}+4Tiᵢ^{4.} (2)

Experimental data have shown that for TiO₂ doped with Ga and other trivalent atoms, such as iron (Fe) and magnesium (Mn), O vacancies are the dominant compensation mechanism at high temperatures and oxygen partial pressures. The creation of O vacancies reduces the coordination number of the Ti atoms. The reduced coordination of the Ti atoms and the O vacancy sites result in an increased ability of the film to trap hydrogen/deuterium atoms.

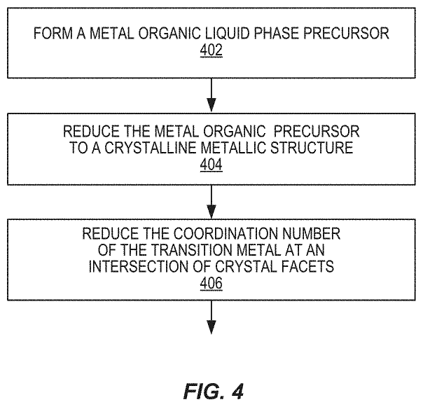

FIGS. 4, 5, and 6 illustrate three exemplary methods for reducing the coordination number of metal atoms in a metal or metal alloy.

FIG. 4 illustrates a first exemplary method for reducing the coordination number of metal atoms. The method comprises forming a metal organic liquid phase precursor (step 402), reducing the metal acetylacetonate precursor to a metallic structure (step 404), and reducing the coordination number of the transition metal (step 406), such as at an intersection of crystal facets.

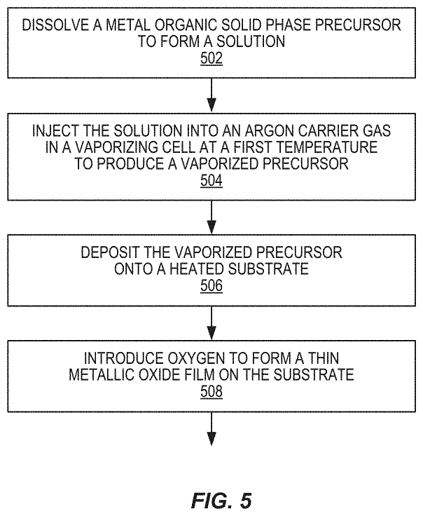

FIG. 5 illustrates a second exemplary method for reducing the coordination number of metal atoms. The method comprises the following steps. First, a metal organic solid phase precursor is dissolved to form a solution (step 502). Second, the solution is then injected into an inert carrier gas (e.g., argon) in a vaporizing cell at a first temperature to produce a vaporized precursor (step 504). The vaporized precursor is then deposited onto a heated substrate (step 506). The substrate is heated to or above a pre-determined temperature required for removal of the organic portion of the precursor. Once the organic portion is removed from the precursor, a thin film of metal oxide is formed on the substrate (step 508) by the introduction of oxygen. This is because oxidation takes place only on or near the substrate.

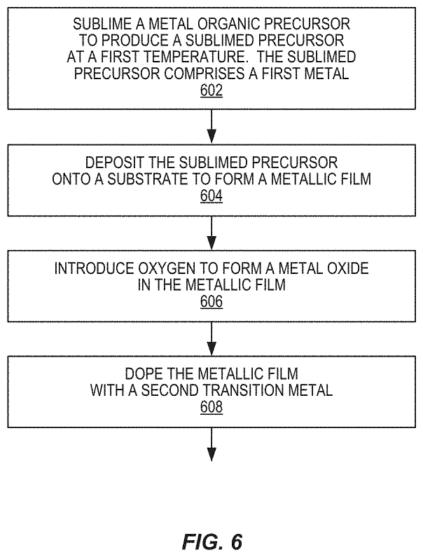

FIG. 6 illustrates a third exemplary method for reducing the coordination number of metal atoms. The method comprises subliming a metal organic precursor to produce a sublimed precursor at a first temperature (step 602). The sublimed precursor is used to create a doped metallic film structure. The sublimed precursor is deposited onto a substrate to form a metallic film (step 604) and oxygen is introduced to form a metal oxide in the metallic film (step 606). The sublimed precursor is doped with a second transition metal, for example, gallium (step 608).

The present invention may be carried out in other specific ways than those herein set forth without departing from the scope and essential characteristics of the invention. The present embodiments are, therefore, to be considered in all respects as illustrative and not restrictive, and all changes coming within the meaning and equivalency range of the appended claims are intended to be embraced therein.

What is claimed is:

1. A method of decreasing a coordination number of metal atoms in a metallic structure of a transition metal or metal alloy, comprising:
forming a metal organic liquid phase precursor; and
reducing the metal organic liquid phase precursor to a crystalline metallic structure;
wherein on a surface of the metallic structure, the coordination number of the transition metal at an intersection of crystal facets is reduced.

2. The method of claim 1, wherein the metal organic liquid phase precursor comprises a metal acetylacetonate solution.

3. The method of claim 2, wherein the metal acetylacetonate solution is a mixture of metal acetylacetonate, a formaldehyde solution and a 1-octylamine solution, and wherein reducing the metal acetylacetonate solution to a metallic structure comprises:
heating the metal acetylacetonate solution at a first temperature for a first time period;
cooling the heated solution to room temperature;
centrifugally separating the solution to achieve a solid product of nanocrystals; and
rinsing the nanocrystals with ethanol or acetone or a mixture of both;

4. The method of claim 3, wherein the first temperature is between 200° C. and 300° C.

5. The method of claim 3, wherein the first time period is a minimum of five hours.

6. The method of claim 3, further comprising rinsing the nanocrystals with ethanol, acetone or a mixture of both for two to five times.

7. The method of claim 3, wherein the formaldehyde solution is 40%.

8. The method of claim 2, wherein reducing the metal acetylacetonate solution to a metallic structure comprises:
heating a substrate made of a borosilicate glass to a first temperature; and
depositing the metal acetylacetonate solution onto the substrate using a pulse sequence.

9. The method of claim 8, wherein the pulse sequence comprises the metal acetaylacetonate solution carried by N₂, N₂ purge, air, and N₂ purge.

10. The method of claim 8, wherein the first temperature is between 350° C. and 400° C.

11. The method of claim 1, wherein the transition metal or metal alloy comprises one or more of the following: Ti, Zr, Hf, Cr, V, Nb, Ta, Mo, W, Fe, Ru, Rh, Ir, Ni, Pd, Pt, Cu, Ag, Au, Zn, Al, In, Sn, and Pb.

12. A method of reducing a coordination number of metal atoms in a metallic oxide film, the metal oxide film comprising a transition metal or metal alloy, comprising:
dissolving a metal organic solid phase precursor to form a solution;
injecting the solution into an inert carrier gas in a vaporizing cell at a first temperature to produce a vaporized precursor;
depositing the vaporized precursor onto a heated substrate, wherein the substrate is heated to a pre-determined temperature required to remove an organic portion from the precursor; and
introducing oxygen to form a thin metallic oxide film on the substrate;
wherein metal atoms at a surface of the metallic oxide film have a reduced coordination number.

13. The method of claim 12, wherein the metal organic solid phase precursor comprises a metal 2,2,6,6-tetramethylheptane-3,5-dionato dissolved into n-butylhexane.

14. The method of claim 13, further comprising:
heating the metallic oxide film in an inert gas atmosphere;
reducing the metallic oxide to remove oxygen atoms; and
creating vacancies to reduce the coordination number of the metal atoms in the metallic oxide film.

15. The method of claim 12, wherein the substrate comprises sapphire.

16. The method of claim 12, wherein the first temperature is between 240° C. and 260° C.

17. The method of claim 12, wherein the pre-determined temperature is between 275° C. and 325° C.

18. The method of claim 12, wherein the transition metal or metal alloy comprises one or more of the following: Ti, Zr, Hf, Cr, V, Nb, Ta, Mo, W, Fe, Ru, Rh, Ir, Ni, Pd, Pt, Cu, Ag, Au, Zn, Al, In, Sn, and Pb.

19. The method of claim 12 wherein the inert gas comprises argon.

20. A method of reducing a coordination number of metal atoms in a metal oxide film of a first transition metal, comprising:
subliming a metal organic precursor to produce a sublimed precursor at a first temperature, said sublimed precursor comprising a first transition metal;
depositing the sublimed precursor onto a substrate to form a metallic film;
introducing oxygen to form a metal oxide in the metallic film; and
doping the metallic film with a second transition metal;
wherein the second transition metal creates vacancies in the metallic film and reduces the coordination number of the first transition metal.

21. The method of claim 20, wherein the metal precursor comprises a metal 2,2,6,6-tetramethylheptane-3,5-dionato dissolved in a butylhexane.

22. The method of claim 21, wherein the first transition metal comprises one or more of the following: Ti, Zr, Hf, Cr, V, Nb, Ta, Mo, W, Fe, Ru, Rh, Ir, Ni, Pd, Pt, Cu, Ag, Au, Zn, Al, In, Sn, and Pb.
